(19) United States
(12) Patent Application Publication
(10) Pub. No.: US 2023/0050613 A1
(43) Pub. Date: Feb. 16, 2023

(54) PELLICLE MEMBRANE FOR A LITHOGRAPHIC APPARATUS

(71) Applicant: ASML NETHERLANDS B.V., Veldhoven (NL)

(72) Inventors: Ties Wouter VAN DER WOORD, Eindhoven (NL); Volker Dirk HILDENBRAND, Eindhoven (NL); Inci DONMEZ NOYAN, Eindhoven (NL); Adrianus Johannes Maria GIESBERS, Vlijmen (NL); Alexander Ludwig KLEIN, Eindhoven, (NL)

(73) Assignee: ASML NETHERLANDS B.V., Veldhoven (NL)

(21) Appl. No.: 17/792,464

(22) PCT Filed: Dec. 15, 2020
(86) PCT No.: PCT/EP2020/086067

§ 371 Date: Jul. 13, 2022

(30) Foreign Application Priority Data
Jan. 16, 2020 (EP) 20152141.6
Jun. 11, 2020 (EP) 20179484.9
Aug. 31, 2020 (EP) 20193717.4

(51) Int. Cl. G03F 1/62; G03F 7/20

(52) U.S. Cl. CPC G03F 1/62; G03F 7/705; G03F 7/70983

(57) ABSTRACT

A pellicle membrane for a lithographic apparatus, the membrane including a matrix including a plurality of inclusions distributed therein. A method of manufacturing the pellicle membrane, a lithographic apparatus including the pellicle membrane, a pellicle assembly for use in a lithographic apparatus including the membrane, as well as the use of the pellicle membrane in a lithographic apparatus or method.

### CROSS-REFERENCE TO RELATED APPLICATIONS

This application claims priority of EP application 20152141.6 which was filed on Jan. 16, 2020, EP application 20179484.9 which was filed on Jun. 11, 2020 and EP application 20193717.4 which was filed on Aug. 31, 2020 which are incorporated herein in its entirety by reference.

The present invention relates to a pellicle membrane for a lithographic apparatus, an assembly for a lithographic apparatus, and a use of a pellicle membrane in a lithographic apparatus or method.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A lithographic apparatus includes a patterning device (e.g. a mask or reticle). Radiation is provided through or reflected off the patterning device to form an image on a substrate. A membrane assembly, also referred to as a pellicle, may be provided to protect the patterning device from airborne particles and other forms of contamination. Contamination on the surface of the patterning device can cause manufacturing defects on the substrate.

Pellicles may also be provided for protecting optical components other than patterning devices. Pellicles may also be used to provide a passage for lithographic radiation between regions of the lithography apparatus which are sealed from one another. Pellicles may also be used as filters, such as spectral purity filters or as part of a dynamic gas lock of a lithographic apparatus.

A mask assembly may include the pellicle which protects a patterning device (e.g. a mask) from particle contamination. The pellicle may be supported by a pellicle frame, forming a pellicle assembly. The pellicle may be attached to the frame, for example, by gluing or otherwise attaching a pellicle border region to the frame. The frame may be permanently or releasably attached to a patterning device.

Due to the presence of the pellicle in the optical path of the EUV radiation beam, it is necessary for the pellicle to have high EUV transmissivity. A high EUV transmissivity allows a greater proportion of the incident radiation through the pellicle. In addition, reducing the amount of EUV radiation absorbed by the pellicle may decrease the operating temperature of the pellicle. Since transmissivity is at least partially dependent on the thickness of the pellicle, it is desirable to provide a pellicle which is as thin as possible whilst remaining reliably strong enough to withstand the sometimes hostile environment within a lithography apparatus.

It is therefore desirable to provide a pellicle which is able to withstand the harsh environment of a lithographic apparatus, in particular an EUV lithography apparatus. It is particularly desirable to provide a pellicle which is able to withstand higher powers than previously.

Whilst the present application generally refers to pellicles in the context of lithography apparatus, in particular EUV lithography apparatus, the invention is not limited to only pellicles and lithography apparatus and it is appreciated that the subject matter of the present invention may be used in any other suitable apparatus or circumstances.

For example, the methods of the present invention may equally be applied to spectral purity filters. Some EUV sources, such as those which generate EUV radiation using a plasma, do not only emit desired ‘in-band’ EUV radiation, but also undesirable (out-of-band) radiation. This out-of-band radiation is most notably in the deep UV (DUV) radiation range (100 to 400 nm). Moreover, in the case of some EUV sources, for example laser produced plasma EUV sources, the radiation from the laser, usually at 10.6 microns, presents a significant out-of-band radiation.

In a lithographic apparatus, spectral purity is desired for several reasons. One reason is that the resist is sensitive to out of-band wavelengths of radiation, and thus the image quality of patterns applied to the resist may be deteriorated if the resist is exposed to such out-of-band radiation. Furthermore, out-of-band radiation infrared radiation, for example the 10.6 micron radiation in some laser produced plasma sources, leads to unwanted and unnecessary heating of the patterning device, substrate, and optics within the lithographic apparatus. Such heating may lead to damage of these elements, degradation in their lifetime, and/or defects or distortions in patterns projected onto and applied to a resist-coated substrate.

A typical spectral purity filter may be formed, for example, from a silicon foundation structure (e.g. a silicon grid, or other member, provided with apertures) that is coated with a reflective metal, such as molybdenum. In use, a typical spectral purity filter might be subjected to a high heat load from, for example, incident infrared and EUV radiation. The heat load might result in the temperature of the spectral purity filter being above 800° C. Under the high head load, the coating can delaminate due to a difference in the coefficients of linear expansion between the reflective molybdenum coating and the underlying silicon support structure. Delamination and degradation of the silicon foundation structure is accelerated by the presence of hydrogen, which is often used as a gas in the environment in which the spectral purity filter is used in order to suppress debris (e.g. debris, such as particles or the like), from entering or leaving certain parts of the lithographic apparatus. Thus, the spectral purity filter may be used as a pellicle, and vice versa. Therefore, reference in the present application to a ‘pellicle’ is also reference to a ‘spectral purity filter’. Although reference is primarily made to pellicles in the present application, all of the features could equally be applied to spectral purity filters.

The present invention has been devised in an attempt to address at least some of the problems identified above.

### SUMMARY OF THE INVENTION

According to a first aspect of the present invention, there is provided a pellicle membrane for a lithographic apparatus, said membrane comprising a matrix including a plurality of inclusions distributed therein.

The inclusions are discrete areas of a material that is different to the material of the matrix. The materials of the inclusions and the matrix may be chemically distinct. The materials of the inclusions and the matrix may have different morphologies.

The inclusions may be in the form of crystals. The inclusions, which may be crystals, may be randomly distributed. The inclusions may be amorphous, but are preferably crystalline.

In this way, the pellicle membrane may be considered as a composite material. Other pellicle membranes comprise stacked layers of materials. In other pellicle membranes, an emissive metallic layer is provided on a face of the pellicle membrane in order to increase the emissivity of the pellicle. The increase in emissivity reduces the operating temperature of such pellicles. Even so, such pellicles are susceptible to island formation, which is when the thin metallic layer dewets from the underlying layer and forms discrete islands of the metal. Island formation decreases the emissivity of the metallic layer and thereby increases the operating temperature of the pellicle. The increased operating temperature results in more dewetting and island formation, and ultimately may lead to failure of the pellicle if this continues for too long. Once the metallic layer has dewetted from the pellicle membrane, it is necessary to replace the pellicle membrane. The present invention overcomes such difficulties by providing a plurality of inclusions, preferably in the form of crystals, in a matrix. As such, the pellicle membranes according to the present invention are less susceptible to dewetting and island formation.

The crystals or inclusions may be randomly distributed in the matrix. Since the crystals or inclusions are present in order to increase the emissivity of the membrane, there is no particular requirement for the crystals to be uniformly distributed.

The inclusions or crystals may comprise a first material and the matrix may comprise a second material. Preferably, the emissivity of the first material is greater than the emissivity of the second material. In another embodiment, the emissivity of the second material is greater than the emissivity of the first material.

As such, the matrix and the inclusions/crystals may serve different roles. The crystals may be made of a highly emissive material, in particular a material that is relatively more emissive than the matrix material. As such, the crystals increase the overall emissivity of the pellicle membrane and thereby reduce its operating temperature. A higher emissivity may also allow for the use of higher power light sources used in lithographic apparatuses as the pellicle will be less susceptible to overheating. By having the emissive material, namely the material which is included in the pellicle membrane for the purpose of increasing the emissivity of the membrane, in the form of crystals distributed in a matrix, the problem of dewetting and island formation is addressed. In addition, due to the possibility of dewetting in pellicle membranes which include an emissive metallic layer, the metallic layer needs to be thick enough to reduce the likelihood of island formation. As such, the metallic layer may be thicker than would be required purely from an emissivity perspective. Thicker metallic layers reduces the transmissivity of the pellicle membrane, which in turn reduces the throughput of the lithographic apparatus since a reduced amount of light energy is available for imaging. In the present invention, it is possible to include a lower amount of emissive material than previously was possible. As such, the pellicle membranes according to the present invention are able to have a lower amount of emissive material relative to earlier pellicle membranes. This has the advantage of increasing the transmissivity of the pellicle membrane. The matrix material may be made of a material which is able to provide mechanical strength and structure to the pellicle membrane. The matrix material may have a lower emissivity than the crystals, but have greater mechanical strength. In this way, the composite material of the pellicle membrane of the present invention is able to have the mechanical strength required for use in a lithographic apparatus as well as high emissivity to control the operating temperature of the membrane when in use.

The crystals or inclusions may comprise molybdenum silicide, zirconium silicide, ruthenium silicide, tungsten silicide, or combinations thereof.

These materials have high emissivity and are able to withstand the operating conditions of an EUV lithographic apparatus. They have high melting points and are electrically conductive. Electrical conductivity is proportional to the emissivity of a material.

The matrix may comprise silicon. Any allotrope or morphology of silicon may be used. For example, the silicon may comprise polycrystalline silicon, amorphous silicon, nanocrystalline silicon, monocrystalline silicon, or combinations thereof. Silicon has good EUV transmissivity. Silicon is also highly etch-selective with regards to silicon oxide, which is often used as a sacrificial layer in manufacture. In addition, the coefficient of thermal expansion of silicon, particularly p-Si, is close to that of the silicon substrate on which pellicle membranes are manufactured. As such, the pre-stress level in the material is more easily obtained.

The matrix may comprise silicon nitride. Silicon nitride has a low coefficient of thermal expansion and has a high melting point. It is therefore suitable for use in a lithographic apparatus since it is able to withstand high temperatures. It also has the necessary mechanical strength to withstand the conditions within an operating EUV lithographic apparatus. Similarly, the matrix may alternatively or additionally comprise silicon carbide.

The membrane may not include a metallic coating. As described, in certain pellicles, a metallic layer is included to increase the emissivity of the pellicle, but such membranes are in a high energy state and are susceptible to dewetting and island formation. The present invention includes discrete portions of emissive material throughout a matrix and so these discrete portions of emissive material are not in a high energy state. In use, pellicle membranes lie in the direct light path of the radiation, such as EUV radiation, used in the lithographic apparatus. This, along with operation at low ambient pressures, results in the membrane reaching high temperatures, which can be in excess of 600° C. This can facilitate chemical and structural degradation of the pellicle membrane that may lead to a loss of imaging performance or even failure of the pellicle. In order to reduce the operating temperature of a pellicle, one or more emissive layers are generally included which increase the emissivity of the pellicle and thereby reduce the operating temperature of the pellicle at a given power. Continuous membrane pellicles provided with emissive layers typically have operating temperatures in the range of 400-650° C. in the EUV lithographic apparatus, with source EUV power in the range of 150 to 300 W (at the intermediate focus), higher temperatures may be expected with higher power sources. In addition, there may be provided a capping layer which slows or prevents chemical degradation of the pellicle membrane. In order to maintain acceptable transmissivity and infrared (IR) emissivity of the pellicle, the one or more emissive metallic or conducting layer is thin. However, metallic films deposited on an inert substrate are in an energetically unfavourable state. The heating of a thin metallic film applied on top of an inert (non-metallic) substrate can lead to thermal instability at temperatures well below the melting point of the metal. As sufficient activation energy is provided, the thin film forms holes through a surface diffusion process and the holes grow with time at a rate strongly dependent on temperature. When the holes coalesce, the material on the surface forms irregularly shaped islands. This process is referred to as dewetting and island formation. It is possible to reduce dewetting and island formation by providing an adhesion layer between the metallic film and the substrate, but the metallic film still remains in an energetically unfavourable state. The thin metallic layer applied on the pellicle, once broken into islands loses its high emissivity property and thus is rendered useless.

The pellicle membrane may have a thickness of from about 10 nm to about 50 nm. It will be appreciated that a thinner membrane will have a greater transmissivity, but will be mechanically weaker than a thicker membrane.

The pellicle membrane may be porous. Since it is not necessary to provide a closed layer, the membrane may be porous. One advantage of this is that any pressure difference across the pellicle membrane is reduced, so there is less likelihood of sagging. As such, the minimum required level of pre-stress or residual stress is lower than its continuous-film counterpart.

The membrane may not comprise multiple stacked layer. In other pellicle membranes there are a series of stacked layers, such as a pellicle core and an emissive metallic layer. These layers may delaminate from one another during use, which is not desirable. These stacked layers also need to be precisely lain down in a specific order, so the manufacture of such pellicles can be lengthy and complicated. The present invention removes the need for multiple stacked layers and this may make manufacture shorter and less complicated.

The molybdenum zirconium, tungsten, and/or ruthenium may be present in the pellicle membrane in an amount of from about 2% to about 40% (atomic %), in an amount of from about 2% to about 30% (atomic %), from about 2% to about 20% (atomic %), or from about 5% to about 10% (atomic %). The emissivity of a pellicle membrane is largely related to the amount of emissive material (which is material included in the membrane to specifically increase emissivity). Lower amounts of such materials lead to lower emissivity. It was thought that this would lead to an increase in operating temperature since the membrane is less efficient in radiating any absorbed power away. However, with decreasing amounts of emissive materials, the transmissivity of the pellicle increases which lowers the amount of absorbed power.

The membrane may be a pellicle core. As such, one or more other layers may be provided to alter the properties of the membrane. The pellicle core may be attached to a frame to provide a pellicle assembly.

The matrix material may be non-filamentary. By non-filamentary, it is meant that the matrix material is not in the form of filaments, such as carbon nanotubes or nanotubes of other materials.

The matrix material may not comprise carbon. As such, the matric material may be a material other than carbon.

According to a second aspect of the present invention, there is provided a method of manufacturing a pellicle membrane according to the first aspect of the present invention. The method may comprise reactive physical vapour deposition or chemical vapour deposition. The method may comprise co-sputtering. The method may comprise sputtering from a single target having a composition with a given elemental ratio of the target components, in order to achieve better deposition uniformity across the deposition substrate.

The method may further include a steal of annealing. The annealing step may take place at any suitable temperature. For example, the annealing may be undertaken at temperatures above 500° C., above 600° C., above 700° C., or above 800° C. Annealing provides the pellicle membrane with its final density and forms crystals in the matrix. The difference in the coefficient of thermal expansion of the pellicle membrane and that of the silicon substrate on which it is formed provides the required level of pre-stress within the membrane. The annealing may take place at temperatures up to 1200° C., up to 1100° C., up to 1000° C., or up to 900° C. It will be appreciated that higher annealing temperatures could be used if required.

According to a third aspect of the present invention, there is provided a lithographic apparatus comprising the pellicle membrane according to the first aspect of the present invention.

According to a fourth aspect of the present invention, there is provided a pellicle assembly for use in a lithographic apparatus, said pellicle assembly comprising the pellicle membrane according to the first aspect of the present invention.

According to a fifth aspect of the present invention, there is provided the use of a pellicle membrane according to the first aspect in a lithographic apparatus or method.

According to a sixth aspect of the present invention, there is provided a method of controlling the composition of a pellicle membrane, the method comprising providing first and second sputtering targets, and adjusting the power provided to one or both of the first and second sputtering targets to adjust the composition of the pellicle membrane.

The method according to the sixth aspect of the present invention may be used to manufacture a pellicle membrane according to any aspect of the present invention.

Controlling the ratio of components of a pellicle membrane is not trivial. One possible method would be to deposit a multi-layer structure of the components which would then intermix during an annealing step. This method is limited by the thickness which can be deposited accurately and the amount of intermixing of the individual layers during annealing. This may result in insufficient levels of stress within the ultimate film, which would prevent its use as a free-standing film.

The method of the present invention allows for better control of the composition of a pellicle membrane. By co-sputtering of the two materials and by using different powers applied to the sputtering targets, it is possible to carefully adjust the ultimate ratio of the matrix material to the inclusion material in the ultimate pellicle membrane. In this way, the optimal balance between transmissivity and emissivity of the pellicle membrane can be achieved.

The first sputtering target may comprise a matrix material. The matrix material may be any matrix material described herein. As such, the first sputtering target may comprise silicon or silicon nitride. The matrix materials provide physical strength to the pellicle membrane and also serve to support the inclusion materials.

The second sputtering target may comprise an inclusion material. The inclusion material is preferably a material which has higher emissivity than the matrix material. The inclusion material may be any inclusion material described herein. As such, the second sputtering target may comprise molybdenum silicide, zirconium silicide, ruthenium silicide, tungsten silicide, or combinations thereof. The inclusion material serves to increase the emissivity of the pellicle membrane.

By adjusting the relative power applied to the first and second targets, it should be understood that the absolute magnitude of the power applied to each target may be the same or different. In order to increase the relative amount of one material in the final pellicle membrane, the power applied to the respective sputtering target may be increased. Of course, it will be appreciated that the relative power applied to the first and second targets may be adjusted by keeping the power applied to one target the same and increasing or decreasing the power applied to the other target.

More than two sputtering targets may be used, if required.

The method comprises a target power of from 50 to 1000 W. As the power applied to the target may be varied to adjust the composition of the final pellicle membrane, any suitable power may be used. A power is suitable if it is sufficient to allow the material to be sputtered and incorporated into the final pellicle membrane. If the power is too low, it may be insufficient to result in effective sputtering of the material.

The method may comprise providing a target power of from 50 W to around 300 W to the second sputtering target to provide a pellicle membrane having a vol% of the inclusion material of from 10 to 60 vol%, preferably from 15 to 50 vol%. It has been found that applying a power of between 50 W to 300 W, that a pellicle membrane having from around 10 to around 60 vol% of the sputtered material can be produced. As such, according to any aspect of the present invention, the pellicle membrane may have a composition of from around 10 to around 60 vol% of the inclusion material, preferably from around 15 to around 50 vol% of the inclusion material. The balance of the volume of the pellicle membrane may comprise the matrix material. In embodiments, the matrix material comprises from around 90 to around 40 vol% of the pellicle membrane. In embodiments, the matrix material comprises around 90 vol%, around 80 vol%, around 70 vol%, around 60 vol%, around 50 vol%, or around 40 vol% of the pellicle membrane. The inclusion material may be present in corresponding amounts to balance the total volume of the pellicle membrane. In embodiments, the pellicle membrane has a minimum pre-stress of 100 MPa. The stress in the deposited layer according to the methods of the present invention or in the pellicle membrane according to any aspect of the present invention shows a linear dependency based on the amount of molybdenum included. In particular, where the pellicle membrane comprises around 4 atomic% of molybdenum, the stress in the pellicle membrane after annealing is around -200 MPa. At around 7.5 atomic% of molybdenum, the stress in the pellicle membrane after annealing is around 100 MPa. At higher amounts of molybdenum, the stress increase further. For example at around 16 atomic % of molybdenum, the stress after annealing is around 400 MPa, and at around 20 atomic% molybdenum, the stress after annealing is around 800 MPa.

According to a seventh aspect of the invention there is provided a method of designing a membrane for a lithographic apparatus, the membrane comprising a matrix including a plurality of inclusions distributed therein and being characterised by an output property which is at least partially dependent on an input property, the method comprising: receiving a set of input values associated with the input property; generating, using semi-empirical thermodynamic modelling, a set of modelled membranes, each modelled membrane being modelled based on an input value of the set of input values associated with the input property; predicting, based on the model, an output value associated with the output property for each of the set of modelled membranes; selecting one or more membranes from the set of modelled membranes based on the predicted output values; and outputting one or more input values from the set of input values based on the selected one or more membranes.

Using this method, properties of the pellicle membrane can be determined so as to optimise the output properties of a pellicle membrane for a given application. The one or membranes may be selected based on their predicted output values being determined to be optimal or acceptable. The outputted one or more input values are those used to model the modelled membranes which have been selected. The outputted one or more input values may be used as input values for a fabrication process to fabricate a membrane. Such a membrane may be referred to as an optimal membrane or an optimised membrane.

Using this method, such membranes may be virtually tested without necessitating the fabrication and testing of a range of membranes with different input properties. Beneficially, this method provides a method of designing an optimal membrane at a greatly reduced cost and/or duration compared to conventional methods. The method may be computer implemented.

The semi-empirical thermodynamic modelling may comprise the CALculation of PHAse Diagrams (CALPHAD) method.

The method may further comprise validating one or more values using experimental data.

The data may comprise empirically measured data. The data may comprise data from a catalogue of measured properties. The values may be the input and/or output values. The values may comprise other values associated with the model, for example a Gibbs energy.

The method may further comprise: receiving a set of second input values associated with a second input property, wherein the output property is at least partially dependent on the second input property; and outputting one or more second input values from the set of second input values based on the selected one or more membranes; wherein each modelled membrane is modelled additionally based on a second input value of the set of second input values associated with the second input property.

That is, the method may comprise modelling a membrane based on multiple input properties.

The method may further comprise: predicting, based on the model, a second output value associated with a second output property for each of the set of modelled membranes, the second output property being at least partially dependent on the input property and/or second input property; wherein the one or more membranes are selected additionally based on the predicted second output values.

That is, the method may comprise determining multiple output properties of a membrane. The selected membrane(s) may be selected based on optimal and/or acceptable values of the output value and the second output value.

Selecting the one or more membranes may be based on either comparing a predicted output value of a first membrane of the set of modelled membranes with a predicted output value of a second membrane of the set of modelled membranes; or comparing a predicted output value of a first modelled membrane of the set of modelled membranes with a threshold value.

That is, a modelled membrane may be selected based on it being deemed better or more optimal in comparison to another modelled membrane. Alternatively, a modelled membrane may be selected based on it exceeding a threshold value, for example a level of acceptability associated with the output value. In some instances, a modelled membrane may only be selected if it is both deemed better or more optimal in comparison to another modelled membrane, and exceeds a threshold value.

The predicted output value may be an output value or a second output value. The comparison may include a determination that the predicted output value of the first membrane is greater than or less than the predicted output value of the second membrane. The threshold value may denote a desired value associated with the output property, beyond which threshold a pellicle membrane with that output property is determined desirable. The threshold value may denote an acceptable value associated with the output property, beyond which threshold a pellicle membrane with that output property is determined acceptable.

The input property, and optionally the second input property, may comprise one of: matrix composition, inclusion concentration, inclusion composition, inclusion distribution, membrane thickness, membrane thickness variation, membrane porosity, amount of membrane pre-stress, fabrication method, and properties associated with the fabrication method, processing method, annealing temperature, annealing heating gradient, gas atmosphere. This list is non-exhaustive and other input properties may affect output properties of the membrane, whether mentioned herein or otherwise.

The output property, and optionally the second output property, may comprise one of: inclusion concentration, inclusion distribution, membrane thickness, membrane thickness variation, membrane porosity, amount of membrane pre-stress, membrane emissivity, membrane transmissivity, membrane sensitivity. This list is non-exhaustive and other output properties may be used to characterise the membrane, whether mentioned herein or otherwise.

The method may further comprise fabricating a membrane using the outputted one or more input values, and optionally the outputted one or more second input values. That is, the outputted values may be used as inputs to a fabrication process.

According to an eighth aspect of the invention, there is described a pellicle membrane for a lithographic apparatus, designed according to the method of aspect seven.

According to a ninth aspect of the invention, there is described a computer program comprising instructions operable to execute the method of aspect seven.

According to a tenth aspect of the invention, there is described a computer storage medium comprising the computer program of aspect nine.

It will be appreciated that features described in respect of one embodiment may be combined with any features described in respect of another embodiment and all such combinations are expressly considered and disclosed herein.

### BRIEF DESCRIPTION OF THE DRAWINGS

Embodiments of the invention will now be described, by way of example only, with reference to the accompanying schematic drawing in which corresponding reference symbols indicate corresponding parts, and in which:

FIG. 1 depicts a lithographic apparatus according to an embodiment of the invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

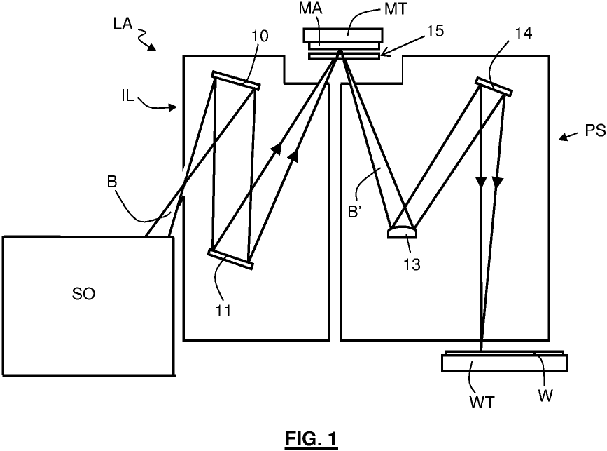

FIG. 1 shows a lithographic system including a pellicle 15 (also referred to as a membrane assembly) according to the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, the pellicle 15 is depicted in the path of the radiation and protecting the patterning device MA. It will be appreciated that the pellicle 15 may be located in any required position and may be used to protect any of the mirrors in the lithographic apparatus.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure which is arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered to be a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

In an embodiment the membrane assembly 15 is a pellicle for the patterning device MA for EUV lithography. The membrane assembly 15 of the present invention can be used for a dynamic gas lock or for a pellicle or for another purpose. In an embodiment the membrane assembly 15 comprises a membrane formed from the at least one membrane layer configured to transmit at least 90% of incident EUV radiation. In order to ensure maximized EUV transmission and minimized impact on imaging performance it is preferred that the membrane is only supported at the border.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

In the method according to the sixth aspect of the present invention, the ratio (atomic or mass) of the matrix material to the inclusion material may be adjusted by adjusting the power applied to a sputtering target comprising the matrix material and/or adjusting the power applied to a sputtering target. The following description refers to a silicon matrix and molybdenum silicide crystal inclusions, but it will be appreciated that this is for example only and it is equally applicable to any combination of matrix material and inclusion material described herein.

Table 1 below demonstrates the difference in the amount of molybdenum silicide in a pellicle membrane and how it depends on the power applied to the molybdenum silicide target.

As can be seen from Table 1 below, by increasing the power applied to the molybdenum silicide target, it is possible to increase the density of the ultimate pellicle membrane and to also increase the vol% of molybdenum silicide in the pellicle membrane. The power applied to the silicon target is maintained, although it will be appreciated that the silicon target power may also be adjusted in other embodiments of the method.

Table 1

| MoSi₂ target Power | Si target power | Density | vol% MoSi₂ |
|---|---|---|---|
| 75 W | 500 W | 3.06 g/cm³ | 18.5 |
| 100 W | 500 W | 3.28 g/cm³ | 24.0 |
| 125 W | 500 W | 3.46 g/cm³ | 28.7 |
| 250 W | 500 W | 4.02 g/cm³ | 43.0 |

The membrane created by the co-sputtering may be subjected to further processing steps as required, including but not limited to annealing. The method of co-sputtering the two target materials allows for the creation of deposited layer which has a residual stress after annealing of less than 1 GPa. As such, such a membrane is able to function as a free-standing pellicle membrane. This has not previously been possible with other methods.

### EXAMPLES

The following examples provide specific embodiments of the present invention. These examples are not intended to be limiting to the scope of the invention.

### Example 1 - MoSi Crystals in an Amorphous SiN Matrix

This pellicle membrane may be manufactured through reactive physical vapour deposition of a MoSi₂ target in a nitrogen-rich environment. The membrane is subsequently annealed at a high temperature, particularly over at least 700° C. The annealing may take place at temperatures up to 1200° C., up to 1100° C., up to 1000° C., or up to 900° C. It will be appreciated that higher annealing temperatures could be used if required. The annealing step provides the membrane with its final density and forms the molybdenum silicide crystals which are randomly scattered within the SiN matrix. The SiN lowers the coefficient of thermal expansion (CTE) of the membrane such that during the annealing step, the difference in the CTE between the membrane and the silicon substrate wafer on which it is made is lowered. This results in the required amount of pre-stress in the membrane. The molybdenum silicide crystals provide the membrane with emissive properties which lower the operating temperature of the pellicle membrane in use. In this way, a membrane with a thickness of less than 25 nm can be provided which has an EUV transmissivity approaching 90% and which is able to withstand exposure to EUV radiation, hydrogen plasma and temperatures seen in scanner conditions using 600W power sources. Alternatively, the pellicle membrane is manufactured through co-sputtering of a molybdenum silicide target and a silicon nitride target, with the power applied to each target being adjusted to change the relative ratio of silicon nitride and molybdenum silicide in the ultimate membrane. As with the pellicle membrane manufactured through reactive physical vapour deposition, there may be a subsequent annealing step.

### Example 2 - MoSi Crystals in a Polycrystalline Silicon (p-Si) Matrix

This pellicle membrane may be manufactured through co-sputtering (physical vapour deposition with multiple targets) using a molybdenum and a silicon target. It will be appreciated that it is also possible to use a molybdenum silicide target and a silicon target. It will be appreciated that it is also possible to use a single target containing molybdenum and silicon in a given ratio. The power provided to the targets may be selected to provide a silicon-rich deposition. After annealing, the molybdenum forms molybdenum silicide while the surplus of silicon forms p-Si resulting in the composite material. P- Si is highly transparent to EUV radiation, so it is possible to increase the thickness of the membrane to make it more physically robust with only a small sacrifice in EUV transmissivity. In this way, a membrane with a thickness of around 20 nm can be manufactured which has an EUV transmissivity of over 90%. If required, a slightly thicker membrane of around 40 nm in thickness can be produced, which still has an EUV transmissivity of around 90%. The thicker membrane requires a lower level of pre-stress in order to prevent sagging of the pellicle membrane.

### Example 3 - MoSi Crystals in a SiC Matrix

The advantage of this combination is mainly EUV transmission. Carbon absorbs less EUV than Nitrogen and should give a ~3% EUVT benefit over MoSiN if all Nitrogen is replaced by Carbon.

### Selection of Membrane Properties

The pellicle membrane can be characterised using a number of properties, for example: matrix density, matrix composition, inclusion concentration (e.g. vol% within matrix, and/or relative concentration of materials within the inclusions), inclusion composition, inclusion distribution, membrane thickness, membrane thickness variation, membrane porosity, amount of membrane pre-stress, membrane emissivity, membrane transmissivity, membrane sensitivity (e.g. sensitivity to temperature, pressure). External properties may also affect properties of the pellicle membrane, for example: fabrication method, and properties associated with the fabrication method e.g. the power applied to a sputtering target in a sputtering or co-sputtering method, annealing method (e.g. electron beam annealing, rapid thermal annealing), and properties associated with the annealing method e.g. annealing temperature, annealing heating gradient, properties associated with other processing steps, and the gas atmosphere in which a fabrication annealing, or other processing step takes place. Annealing may be considered a processing step.

Some properties, referred to herein as input properties, do not significantly depend on other properties. Input properties may be selected by a user as an input to the fabrication of a pellicle membrane. That is, input properties are independent variables relevant to the fabrication of a pellicle membrane. The input properties may be referred to as independent variables. Examples of input properties are matrix composition, inclusion composition, fabrication method.

Some properties, referred to herein as output properties, depend, at least partially, upon other properties. That is, output properties are dependent variables and may be referred to as such. Output properties thus cannot be directly selected, but may be achieved through selection of input properties. Output properties may depend on input properties only, may depend on other output properties only, or may depend on a combination of input and output properties. Examples of output properties are matrix density (which may depend at least on the power applied to a sputtering target) and pellicle transmissivity (which may depend on at least matrix density, matrix composition, membrane thickness). Output properties comprise properties of the membrane itself and can be referred to as membrane properties.

Input properties of the pellicle membrane can be selected so as to optimise the output properties of a pellicle membrane for a given application. Given the large range of properties, and the range of values each property may take, it is not practical to manufacture a pellicle membrane for each combination of properties and values thereof. Instead, modelling the properties of a membrane allows for the selection of an optimal set of properties for pellicle membrane for a given application. Using thermodynamic modelling, a large range of pellicle membranes may be virtually tested. That is, properties of membranes may determined without necessitating the entire process of fabrication and testing of such a membrane. Such a process of fabrication and testing of a membrane may be costly and/or time consuming (e.g. on the order of months). As a result, fabricating and testing membranes with different properties is even more costly and/or time consuming. By iteratively performing virtual testing, a large solution space may be scanned in order to determine an optimal set of properties for a given application, at a greatly reduced cost and/or duration. The determination of an optimal set of properties for a membrane may be referred to as designing a membrane.

Thermodynamic modelling, in particular semi-empirical thermodynamic modelling, can be used. Semi-empirical methods use some experimental data to validate thermodynamic calculations. The experimental data may comprise, for example, a single point of experimental data. Alternatively or additionally, the experimental data may comprise data from a catalogue or database of measured properties of a material e.g. a Gibbs energy database.

In a specific example, the CALculation of PHAse Diagrams (CALPHAD) is used. The CALPHAD methodology models the properties of constituent parts of a system and uses these to predict properties of the entire system. A CALPHAD software package is available at https://gtt-technologies.de/.

In an example method, an input property is scanned (that is, a parameter associated with an input property is varied incrementally from a first value to a second value) and an output parameter predicted for each value of said input property. For example, using the example of a pellicle membrane according to example 2 above (comprising MoSi crystals in a polycrystalline silicon (p-Si) matrix), the temp. The model outputs data comprising a predicted temperature sensitivity for each annealing temperature tested. From the output data, an optimal temperature sensitivity (e.g. the lowest predicted temperature sensitivity) may be identified, and thus an optimal annealing temperature associated with the optimal 3temperature sensitivity identified. This optimal annealing temperature may then be used in future fabrication processes in order to make a pellicle membrane with reduced temperature sensitivity.

The above method is a single input, single output modelling method. In another method, multiple outputs may be predicted. For example, the above described model may output data comprising a predicted temperature sensitivity for each annealing temperature and a predicted pellicle membrane transmissivity for each annealing temperature. That is, the output data is a multi-dimensional matrix of values. An optimal temperature sensitivity and/or an optimal transmissivity may be identified, and one or more corresponding optimal annealing temperatures may therefore be identified. One or more annealing temperatures may be identified which yield an acceptable temperature sensitivity and acceptable transmissivity. That is, a range of input values may be identified which yield an acceptable combination of output values.

The above method is a single input, multiple output modelling method. In another example, multiple inputs may be used. For example, using the same example of a pellicle membrane according to example 2, the temperature sensitivity of the pellicle is predicted for a range values of a set of input properties: annealing temperatures in the range 500 to 1000° C., heating gradients in the range 1° C. s⁻¹ to 5° C. s⁻¹, cooling gradient in the range 1° C. s⁻¹ to 5° C. s⁻¹ and different gas environments (hydrogen, nitrogen). The model outputs data comprising a predicted temperature sensitivity for each combination of values of each input property. That is, the output data is a multi-dimensional matrix of values. An optimal temperature sensitivity (e.g. the lowest predicted temperature sensitivity) may be identified from the output data, and thus optimal values of the set of input properties associated with the optimal temperature sensitivity identified.

Correspondingly, multiple input, multiple output modelling methods may be used. For example, using an example of a pellicle membrane comprising MoSiN (nitrogen doped MoSi) crystals in a matrix, the temperature sensitivity and pressure sensitivity (e.g. gas pressure) is predicted for a set of input properties: doping methods (e.g. co-sputtering, diffusion from sacrificial layers, implantation) and dopant concentrations (e.g. 0% to 5%). The output is a multi-dimensional matrix of values, from which an optimal set of input and output values or acceptable range of input and output values may be identified.

By outputting optimal input values, said outputted input values can be provided to a fabrication process, for example a membrane can be fabricated using said outputted input values. In this way, an optimised membrane may be fabricated using the design process described above. Alternatively, the outputted input and/or output values may be stored, or may be used as inputs to future design processes.

The above described modelling methods (i.e. design processes) are of particular use for the following use cases.

Sensitivity analysis. Pellicle membranes are typically sensitive to temperature and/or gas pressure. By modelling pellicle membranes with various properties, one or more optimal sets of input properties may be identified which may be used to generate a pellicle membrane with optimised (i.e. reduced) sensitivity. In particular, the following input properties are input to the model: inclusion composition and dopant concentration (e.g. relative concentration of N, Mo and Si in a pellicle membrane comprising MoSiN crystals in a matrix), annealing temperature, annealing gradient, annealing type, annealing atmosphere, pellicle membrane thickness, inclusion distribution (e.g. point defect engineering).

Identifying material combinations. A variety of materials can be used for the inclusions and/or matrix. Modelling as described above can be used to identify optimal combinations of materials. Optimal combinations are determined based on one or more optimal output properties or acceptable ranges of output properties, e.g. membrane transmission and/or stability characteristics. In particular, the following input properties are input to the model: inclusion composition (e.g. inclusion material such as C, Si, Mo, Ru, N, O, B, Hf, Zr, Nb, Y and relative concentrations therof), dopant concentration, fabrication method, doping method.

Optimising fabrication methods. By modelling properties of a pellicle membrane associated with a range of fabrication and/or processing methods, fabrication and processing methods (and optimal properties thereof) may be identified which optimise one or more properties of a pellicle membrane, without physically fabricating a large set of pellicles. In particular, the following input properties are input to the model: fabrication method, doping method, annealing method, annealing temperature, annealing gradient, gas atmosphere.

Considering the selection of an optimal property (or an acceptable property), an optimal or acceptable property may be determined in a number of ways. An optimal property may be determined by comparing the set of output properties predicted by the method, and selecting the optimal (for example largest or smallest) value. An optimal or acceptable property may be determined by comparing the set of output properties predicted by the model to a threshold value, and selecting all predicted output properties which exceed the threshold value.

Where reference is made to the prediction of an output property, it should be understood that the prediction may be a prediction of a value associated with the output property. Similarly, the provision of, or receipt of, an input property, this may comprise the provision or receipt of a value associated with the input property.

The modelling methods described herein may be implemented as instructions in a computer program. That is, the modelling methods may be computer-implemented. Such a computer program may be stored on a computer storage medium.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

While specific embodiments of the invention have been described above, it will be appreciated that the invention may be practiced otherwise than as described.

The descriptions above are intended to be illustrative, not limiting. Thus it will be apparent to one skilled in the art that modifications may be made to the invention as described without departing from the scope of the claims set out below.

1. A pellicle membrane for a lithographic apparatus, the membrane comprising a matrix including a plurality of inclusions distributed therein.

2. The pellicle membrane according to claim 1, wherein the plurality of inclusions comprises a plurality of crystals.

3. The pellicle membrane according to claim 1, wherein the inclusions comprise a first material and the matrix comprises a second material, the emissivity of the first material being greater than the emissivity of the second material.

4. The pellicle membrane according to claim 1, wherein the inclusions comprise molybdenum silicide, zirconium silicide, ruthenium silicide, tungsten silicide, or a combination selected therefrom thereof.

5. The pellicle membrane according to claim 1, wherein the matrix comprises silicon.

6. The pellicle membrane according to claim 5, wherein the matrix comprises silicon nitride and/or silicon carbide.

7. The pellicle membrane according to claim 5, wherein the silicon comprises any one of p-Si, a-Si, nc-Si, mono-Si, or a combination selected therefrom.

8. The pellicle membrane according to claim 1, wherein the membrane does not include a metallic coating and/or wherein the matrix material does not comprise carbon.

9. The pellicle membrane according to claim 1, wherein the membrane has a thickness of from about 10 nm to about 50 nm.

10. (canceled)

11. The pellicle membrane according to claim 1, wherein the membrane does not comprise multiple stacked layers.

12. The pellicle membrane according to claim 1, wherein the inclusions comprise molybdenum silicide, zirconium silicide, ruthenium silicide, tungsten silicide, or a combination selected therefrom and wherein the molybdenum, zirconium, tungsten, and/or ruthenium is present in the pellicle membrane in an amount of from about 2% to about 40% (atomic %), or wherein the pellicle membrane has a composition of from around 10 to around 60 vol% of the inclusion material.

13. (canceled)

14. The pellicle membrane according to claim 1, wherein the matrix material is non filamentary.

15-18. (canceled)

19. A pellicle assembly for use in a lithographic apparatus, the pellicle assembly comprising the pellicle membrane according to claim 1.

20. (canceled)

21. A method of controlling a composition of a pellicle membrane, the method comprising providing a sputtering target, and adjusting power provided to the sputtering target to adjust the composition of the pellicle membrane.

22. The method according to claim 21, comprising providing a first sputtering target and a second sputtering target, and adjusting the power provided to one or both of the first and second sputtering targets to adjust the composition of the pellicle membrane.

23. The method of claim 22, wherein the first sputtering target comprises a matrix material.

24. The method of claim 22, wherein the second sputtering target comprises an inclusion material.

25. (canceled)

26. The method according to claim 21, wherein the power is within the range of from 50 to 1000 W.

27. The method according to claim 21, comprising providing power within the range of from 50 W to around 300 W to the sputtering target to provide a pellicle membrane having a vol% of inclusion material of from 10 to 60 vol%.

28. A method of designing a membrane for a lithographic apparatus, the membrane comprising a matrix including a plurality of inclusions distributed therein and the membrane being characterized by an output property which is at least partially dependent on an input property, the method comprising:
receiving a set of input values associated with the input property;
generating, using semi-empirical thermodynamic modelling, a set of modelled membranes, each modelled membrane being modelled based on an input value of the set of input values associated with the input property;
predicting, based on the model, an output value associated with the output property for each membrane of the set of modelled membranes;
selecting one or more membranes from the set of modelled membranes based on the predicted output values;
outputting one or more input values from the set of input values based on the selected one or more membranes.

29-39. (canceled)
